(19) United States
(12) Patent Application Publication
(10) Pub. No.: US 2025/0006711 A1
(43) Pub. Date: Jan. 2, 2025

(54) DISPLAY APPARATUS

(71) Applicant: Samsung Display Co., Ltd., Yongin-si (KR)

(72) Inventors: Sangshin Lee, Yongin-si (KR); Yeonju Kang, Yongin-si (KR); Sanghoon Kim, Yongin-si (KR); Seungjin Lee, Yongin-si (KR); Yuri Lee, Yongin-si (KR)

(21) Appl. No.: 18/639,601

(22) Filed: Apr. 18, 2024

(30) Foreign Application Priority Data
Jun. 28, 2023 (KR) 10-2023-0083770

(51) Int. Cl. H01L 25/075; H01L 33/24

(52) U.S. Cl. CPC H01L 25/0753; H01L 33/24

(57) ABSTRACT

Provided is a display apparatus including a first display area in which sub-pixels are arranged, and a second display area adjacent to the first display area, and including a second pixel area in which there is a second pixel having a rectangular shape in plan view, and including two first sub-pixels spaced apart from each other in a first direction at a lower portion of the second pixel area, two second sub-pixels, and two third sub-pixels are arranged, and transmission areas surrounding the second pixel area, wherein a portion of one of the first sub-pixels has an arc shape of a circle having a same center as a circular shape of an adjacent one of the transmission areas.

### CROSS-REFERENCE TO RELATED APPLICATION

The present application claims priority to, and the benefit of, Korean Patent Application No. 10-2023-0083770, filed on Jun. 28, 2023, in the Korean Intellectual Property Office, the entire disclosure of which is incorporated herein by reference.

### BACKGROUND

### 1. Field

One or more embodiments relate to a display apparatus.

### 2. Description of the Related Art

Recently, the use of display apparatuses has been diversifying. In addition, because the thickness of a display apparatus is reduced, and the weight thereof is relatively light, the range of use thereof is being widened.

Various functions are added to combine or link to the display apparatus while expanding the area occupied by a display area. As a way to add a variety of functions while expanding the area, research on display apparatuses having an area for adding various functions rather than image display inside the display area has been continuously carried out.

### SUMMARY

One or more embodiments provide a display panel having an enlarged display area in which an image may be displayed even in an area where components, such as electronic elements, are located, and also provide an electronic device having the display panel. However, the above aspects are merely illustrative, and the scope of the present disclosure is not limited thereto.

Additional aspects will be set forth in part in the description that follows and, in part, will be apparent from the description, or may be learned by practice of the presented embodiments of the disclosure.

According to one or more embodiments, a display apparatus includes a first display area in which sub-pixels are arranged, and a second display area adjacent to the first display area, and including a second pixel area in which there is a second pixel having a rectangular shape in plan view, and including two first sub-pixels spaced apart from each other in a first direction at a lower portion of the second pixel area, two second sub-pixels, and two third sub-pixels are arranged, and transmission areas surrounding the second pixel area, wherein a portion of one of the first sub-pixels has an arc shape of a circle having a same center as a circular shape of an adjacent one of the transmission areas.

The two second sub-pixels may be spaced apart in a first diagonal direction and spaced from a center of the second pixel area.

The two third sub-pixels may be spaced apart in a second diagonal direction crossing the first diagonal direction and spaced from the center of the second pixel area.

A shortest distance between one of the first sub-pixels and an adjacent first transmission area of the transmission areas, and a shortest distance between the one of the first sub-pixels and an adjacent second transmission area of the transmission areas, may be substantially equal.

A center of one of the second sub-pixels, a center of one of the third sub-pixels, and a center of the second pixel area may be in a same line.

Centers of the second sub-pixels may be shifted from a line extending in a first diagonal direction while passing through the second pixel area.

Centers of the third sub-pixels may be shifted from a line extending in a second diagonal direction crossing the first diagonal direction and passing through the center of the second pixel area.

A portion of one of the second sub-pixels may have an arc shape of a circle having the same center as the circular shape of the adjacent one of the transmission areas.

The second sub-pixels may be spaced apart in the first direction and spaced from a center of the second display area.

The second sub-pixels may include a (2^{nd}-1) sub-pixel and a (2^{nd}-2) sub-pixel, wherein a shortest distance between the (2^{nd}-1) sub-pixel and an adjacent one of the first sub-pixels, and a shortest distance between the (2^{nd}-1) sub-pixel and a first sub-pixel of an adjacent third pixel, are substantially equal to each other.

A shortest distance between the one of the second sub-pixels and the adjacent one of the first sub-pixels, and a shortest distance between the one of the second sub-pixels and another adjacent first sub-pixel, may be substantially equal to each other.

According to one or more embodiments, a display apparatus includes a first display area in which sub-pixels are arranged, and a second display area adjacent to the first display area, and including a first pixel area in which there is a first pixel having a rectangular shape in a plan view, and including four first sub-pixels, two second sub-pixels, and two third sub-pixels, and transmission areas surrounding the first pixel area, wherein the first sub-pixels are spaced from a center of the first pixel area further than the second sub-pixels and the third sub-pixels.

The first sub-pixels, the second sub-pixels, and the third sub-pixels may have respective circular shapes.

The transmission areas may have respective circular shapes.

A portion of the first pixel area and a portion of one of the transmission areas may overlap.

Two of the first sub-pixels may be spaced from each other in a first diagonal direction and are spaced from the center of the first pixel area, wherein two others of the first sub-pixels are spaced from each other in a second diagonal direction crossing the first diagonal direction and are spaced from the center of the first pixel area.

The first sub-pixels may be configured to emit green light, the second sub-pixels may be configured to emit blue light, and the third sub-pixels may be configured to emit red light.

The first sub-pixels may be electrically connected to a same signal line, and are configured to emit light concurrently or substantially simultaneously.

The first sub-pixels and the second sub-pixels may be electrically connected to a same signal line, and are configured to emit light concurrently or substantially simultaneously.

According to one or more embodiments, a display apparatus includes a first display area in which sub-pixels are arranged, and a second display area adjacent to the first display area, and including a third pixel area in which there is a fourth pixel having a rectangular shape in a plan view and including two first sub-pixels, one second sub-pixel, and two third sub-pixels, and transmission areas surrounding the third pixel area, and wherein the first sub-pixels are spaced apart from each other in a first direction at a lower portion of the third pixel area, wherein the second sub-pixel is at a center of the third pixel area, and wherein the third sub-pixels are spaced apart from each other in the first direction at an upper portion of the third pixel area.

A shortest distance between one of the first sub-pixels and an adjacent first transmission area of the transmission areas, and a shortest distance between the one of the first sub-pixels and an adjacent second transmission area of the transmission areas, may be substantially equal.

A shortest distance between one of the third sub-pixels and an adjacent first transmission area of the transmission areas, and a shortest distance between the one of the third sub-pixels and an adjacent third transmission area of the transmission areas, may be substantially equal to each other.

### BRIEF DESCRIPTION OF THE DRAWINGS

The above and other aspects of embodiments of the disclosure will be more apparent from the following description taken in conjunction with the accompanying drawings, in which:

FIG. 1 is a perspective view showing an electronic device according to one or more embodiments;

FIG. 2 is an exploded perspective view showing an electronic device according to one or more embodiments;

FIG. 3 is a block diagram showing an electronic device according to one or more embodiments;

FIG. 4 is a cross-sectional view illustrating a portion of an electronic device according to one or more embodiments;

FIG. 5 is a plan view schematically illustrating a display panel according to one or more embodiments;

FIG. 6 is a circuit diagram illustrating a sub-pixel circuit connected to each light-emitting diode of a display panel according to one or more embodiments;

FIG. 7 is a plan view illustrating a portion of a first display area of a display panel according to one or more embodiments;

FIG. 8 is a plan view illustrating a portion of a second display area of a display panel according to one or more embodiments;

FIG. 9A is a plan view illustrating a portion of a second display area of a display panel according to one or more embodiments;

FIG. 9B is an enlarged view schematically illustrating a portion of FIG. 9A;

FIG. 10A is a plan view illustrating a portion of a second display area of a display panel according to one or more embodiments;

FIG. 10B is an enlarged view schematically illustrating a portion of FIG. 10A;

FIG. 11A is a plan view illustrating a portion of a second display area of a display panel according to one or more embodiments;

FIG. 11B is an enlarged view schematically illustrating a portion of FIG. 11A;

FIG. 12A is a plan view illustrating a portion of a second display area of a display panel according to one or more embodiments; and

FIG. 12B is an enlarged view schematically illustrating a portion of FIG. 12A.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to” may be construed similarly. It will be understood that when an element or layer is referred to as being “between” two elements or layers, it can be the only element or layer between the two elements or layers, or one or more intervening elements or layers may also be present.

For the purposes of this disclosure, expressions, such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression, such as “at least one of A and B” and “at least one of A or B” may include A, B, or A and B. As used herein, “or” generally means “and/or,” and the term “and/or” includes any and all combinations of one or more of the associated listed items. For example, the expression, such as “A and/or B” may include A, B, or A and B. Similarly, expressions, such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

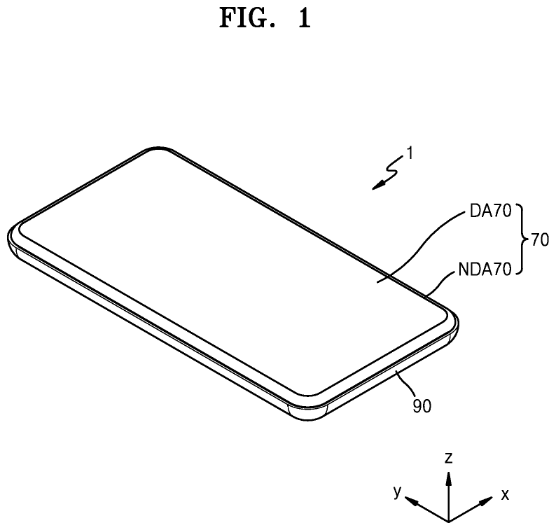

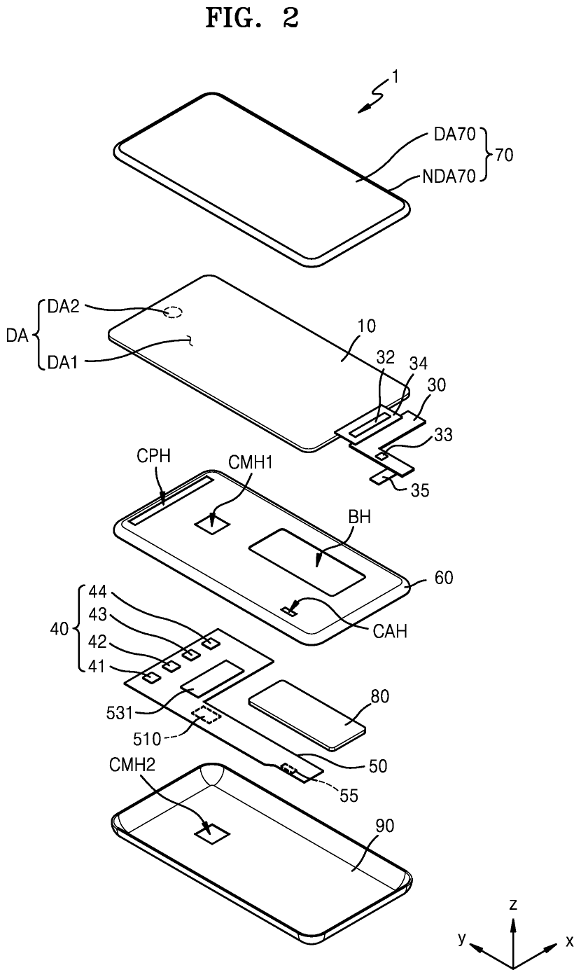

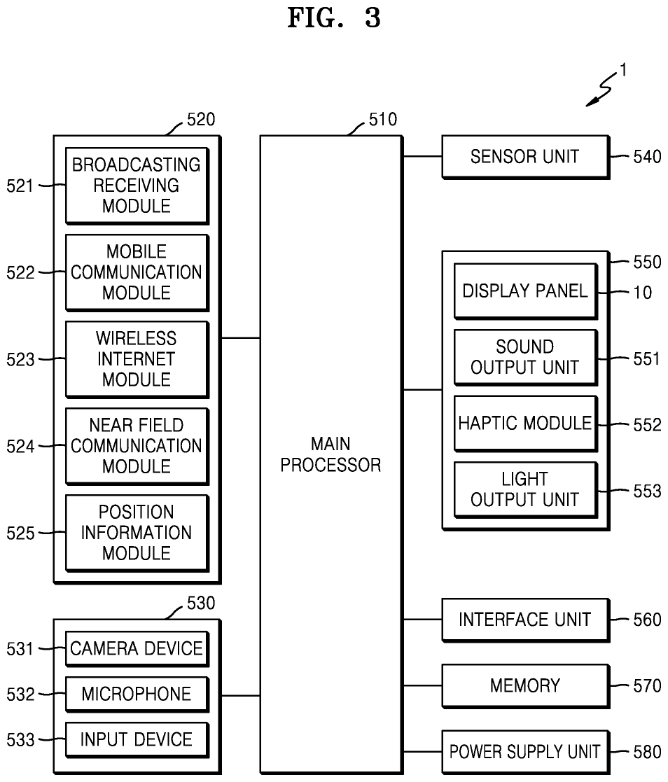

FIG. 1 is a perspective view showing an electronic device according to one or more embodiments, and FIG. 2 is an exploded perspective showing an electronic device according to one or more embodiments. FIG. 3 is a block diagram showing an electronic device according to one or more embodiments.

Referring to FIGS. 1 and 2, an electronic device 1 according to one or more embodiments may be an apparatus for displaying a moving image or a still image, and may be used for a display screen of various products, such as portable electronic devices, for example, a mobile phone, a smart phone, a tablet personal computer (PC), a mobile communication terminal, an electronic notebook, an electronic book, a portable multimedia player (PMP), a navigation system, and an ultra-mobile PC, televisions, laptop computers, monitors, billboards, Internet of Things (IOT), and the like. In addition, the electronic device 1 according to one or more embodiments may be used for a wearable device, such as a smart watch, a watch phone, a glasses type display, or a head mounted display (HMD). In addition, the electronic device 1 according to one or more embodiments may be used as an instrument panel of a vehicle, and a center information display (CID) display located on a center fascia or a dashboard of a vehicle, a room mirror display for replacing a side mirror of a vehicle, and a display located on the rear surface of the front seat.

FIGS. 1 and 2 show that the electronic device 1 according to one or more embodiments is used as a smartphone for convenience of explanation. The electronic device 1 according to one or more embodiments may include a cover window 70, a display panel 10, a display circuit board 30, a display-driving portion 32, a touch-sensor-driving portion 33, a bracket 60, a main circuit board 50, a battery 80, and a lower cover 90.

“Left,” “right,” “up,” “down” in the plan view of the present specification refer to directions when the display panel 10 is viewed in a vertical direction of the display panel 10. For example, “left” represents an −x direction, “right” represents an +x direction, “up” represents a +y direction, and “down” represents a −y direction.

The electronic device 1 may have a rectangular shape in a plan view. For example, the electronic device 1 may have a planar form of a rectangle having short sides in an x direction and long sides in a y direction, as shown in FIG. 1. The edges of the short sides in the x direction and the long sides in the y direction may be formed round or right angle to have a corresponding curvature. The planar form of the electronic device 1 is not limited to a rectangular shape, but can be formed in other polygonal, oval, or unstructured shape.

The cover window 70 may be located on the display panel 10 to cover an upper surface of the display panel 10. For this reason, the cover window 70 may function to protect the upper surface of the display panel 10.

The cover window 70 may include a transmission cover portion DA70 corresponding to the display panel 10, and a light-shielding cover portion NDA70 corresponding to an area except for the display panel 10. The light-shielding cover portion NDA70 may include an opaque material (e.g., a colored opaque material) that shields light. The light-shielding cover portion NDA70 may include a pattern that can be shown to a user if an image is not displayed.

The display panel 10 may be located under the cover window 70. The display panel 10 may overlap the transmission cover portion DA70 of the cover window 70.

The display panel 10 may include a display area DA, and the display area DA may include a first display area DA1 and a second display area DA2. Both the first display area DA1 and the second display area DA2 are areas in which images are displayed, and the second display area DA2 may be an area in which components 40, such as a sensor using visible rays, infrared rays or sound, a camera and the like are located on a lower portion of the second display area DA2. In one or more embodiments, the second display area DA2 may be an area having higher light transmittance and/or sound transmittance than the first display area DA1. In one or more embodiments, if light is transmitted through the second display area DA2, the light transmittance may be about 25% or more, about 30% or more, about 50% or more, about 75% or more, about 80% or more, about 85% or more, or about 90% or more.

The display panel 10 may be a light-emitting display panel including a light-emitting diode. The light-emitting diode may include an organic light-emitting diode including an organic light-emitting layer. In some embodiments, the light-emitting diode may be an inorganic light-emitting diode including an inorganic material. The inorganic light-emitting diode may include a PN diode including materials based on an inorganic material semiconductor. When a voltage is applied to a PN junction diode in a forward direction, holes and electrons may be injected, and energy generated by re-combination of the holes and the electrons may be converted into light energy so that light having a corresponding color may be emitted. The above-described inorganic light-emitting diode may have a width of several to several hundreds of micrometers, and in some embodiments, the inorganic light-emitting diode may be referred to as a micro light-emitting diode (LED).

The display panel 10 may be a rigid display panel that has rigidity and that is not easily bent, or may be a flexible display panel that has flexibility and that is suitably bendable, foldable or rollable. For example, the display panel 10 may be a foldable display panel that may be folded or unfolded, a curved display panel having a bent display surface, a bent or bendable display panel having a bent area other than a display surface, a rollable display panel that may be rolled or unfolded, or a stretchable display panel.

The display panel 10 may be a transparent display panel that is transparently implemented so that objects or backgrounds located on a lower surface of the display panel 10 may be seen from the upper surface of the display panel 10. Alternatively, the display panel 10 may be a reflective display panel that may reflect an object or background on the upper surface of the display panel 10.

A first soft film 34 may be attached to one side edge of the display panel 10. One side of the first soft film 34 may be attached to one side edge of the display panel 10 by using an anisotropic conductive film. The first soft film 34 may be a flexible film that is bendable.

The display-driving portion 32 may be located on the first soft film 34. Control signals and power supply voltages may be applied to the display-driving portion 32, and the display-driving portion 32 may generate signals and voltages for driving the display panel 10, and may output the signals and voltages. The display-driving portion 32 may be formed of an integrated circuit (IC).

The display circuit board 30 may be attached to the other side of the first soft film 34. The other side of the first soft film 34 may be attached to an upper surface of the display circuit board 30 by using an anisotropic conductive film. The display circuit board 30 may be a flexible printed circuit board (FPCB) that may be bent, a rigid printed circuit board (PCB) that is hard and that is not easily bent, or a composite PCB including both the rigid PCB and the FPCB.

A touch-sensor-driving portion 33 may be located on the display circuit board 30. The touch-sensor-driving portion 33 may be formed of an IC. The touch-sensor-driving portion 33 may be attached to the display circuit board 30. The touch-sensor-driving portion 33 may be electrically connected to touch electrodes of a touch screen layer of the display panel 10 through the display circuit board 30.

The touch screen layer of the display panel 10 may detect a user's touch input by using at least one of various touch methods, such as a resistive type method, a capacitive type method, and/or the like. For example, if the touch screen layer of the display panel 10 detects the user's touch input by using the capacitive type method, the touch-sensor-driving portion 33 may apply driving signals to driving electrodes among touch electrodes and may detect voltages charged in mutual capacitance between the driving electrodes and sensing electrodes (hereinafter, referred to as “mutual capacitance”) through the sensing electrodes among the touch electrodes, thereby determining whether or not the user has touched. The user's touch may include a contact touch and/or a proximity touch. The contact touch represents that an object, such as the user's finger or pen, is in direct contact with the cover window 70 located on the touch screen layer. The proximity touch represents that the object, such as the user's finger or pen is located close to the cover window 70, like hovering. The touch-sensor-driving portion 33 may transmit sensor data to the main processor 510 according to detected voltages, and the main processor 510 may analyze the sensor data so that touch coordinates in which touch input occurs, may be calculated.

Sub-pixels of the display panel 10, a scan-driving portion, and a power supply portion for supplying driving voltages for driving the display-driving portion 32 may be additionally arranged on the display circuit board 30. Alternatively, the power supply portion may be integrated with the display-driving portion 32, and in this case, the display-driving portion 32 and the power supply portion may be formed of one IC.

A bracket 60 for supporting the display panel 10 may be located under the display panel 10. The bracket 60 may include plastic, metal, or both plastic and metal. A first camera hole CMH1 into which a camera device 531 is inserted, a battery hole BH in which the battery 80 is located, and a cable hole CAH through which a cable 35 connected to the display circuit board 30 passes, may be formed in the bracket 60. In addition, a component hole CPH that overlaps the second display area DA2 of the display panel 10, may be provided in the bracket 60. The component hole CPH may overlap components 40 of the main circuit board 50 in a third direction (z direction). Thus, the second display area DA2 of the display panel 10 may overlap the components 40 of the main circuit board 50. The component hole CPH may not be formed in the bracket 60, and in this case, the bracket 60 may be located not to overlap the second display area DA2 of the display panel 10 in the third direction (z direction).

The components 40 may overlap the second display area DA2 of the display panel 10. For example, the components 40 may include first through fourth components 41, 42, 43, and 44 that overlap the second display area DA2. The first through fourth components 41, 42, 43, and 44 may be provided as a proximity sensor, an illumination sensor, an iris sensor, a face recognition sensor, and a camera (or an image sensor), respectively. Because the second display area DA2 of the display panel 10 may have corresponding light transmittance, the proximity sensor using ultraviolet (UV) rays may detect an object located close to an upper surface of the electronic device 1, and the illumination sensor may detect brightness of light incident on the upper surface of the electronic device 1. In addition, the iris sensor may capture an image of the iris of a person placed on the upper surface of the electronic device 1, and the camera may capture an image of an object located on the upper surface of the electronic device 1. The components 40 located to overlap the second display area DA2 of the display panel 10 are not limited to the proximity sensor, the illumination sensor, the iris sensor, the face recognition sensor, and the camera, and various sensors to be described later may be located.

The main circuit board 50 and the battery 80 may be located under the bracket 60. The main circuit board 50 may be a PCB or a FPCB.

The main circuit board 50 may include a main processor 510, a camera device 531, a main connector 55, and components 40. The main processor 510 may be formed of an IC. The camera device 531 may be located on both upper and lower surfaces of the main circuit board 50, and each of the main processor 510 and the main connector 55 may be located on any one surface of the upper and lower surfaces of the main circuit board 50.

The main processor 510 may control all functions of the electronic device 1. For example, the main processor 510 may output digital video data to the display-driving portion 32 through the display circuit board 30 so that the display panel 10 may display an image. In addition, the main processor 510 may receive detection data from the touch-sensor-driving portion 33. The main processor 510 may determine whether or not the user has touched in response to the detection data, and may perform an operation corresponding to the user's direct touch or proximity touch. For example, the main processor 510 may analyze the detection data, may calculate the user's touch coordinates, and then may execute an application indicated by an icon touched by the user or may perform an operation. The main processor 510 may be an application processor formed of an IC, a central processing unit (CPU), or a system chip.

The camera device 531 may process a video frame, such as a still image or a moving image obtained by the image sensor in a camera mode to output the processed video frame to the main processor 510. The camera device 531 may include at least one of a camera sensor (e.g., a charge coupled device (CCD), a complementary metal oxide semiconductor (CMOS), etc.), a photosensor (or an image sensor), and/or a laser sensor. The camera device 531 may be connected to the image sensor among the components 40 that overlap the second display area DA2, and may process an image input to the image sensor.

The cable 35 that has passed through the cable hole CAH of the bracket 60 may be connected to the main connector 55, and thus, the main circuit board 50 may be electrically connected to the display circuit board 30.

In addition to the main processor 510, the camera device 531, and the main connector 55, the main circuit board 50 may further include at least one of a wireless communicator (e.g., wireless communication unit) 520, at least one of an input (e.g., input unit) 530, at least one of a sensor (e.g., sensor unit) 540, at least one of an output (e.g., output unit) 550, at least one of an interface (e.g., interface unit) 560, a memory 570, and/or a power supply (power supply unit) 580.

The wireless communicator 520 may include at least one of a broadcasting receiving module 521, a mobile communication module 522, a wireless Internet module 523, a near field communication module 524, and/or a position information module 525.

The broadcasting receiving module 521 may receive a broadcasting signal and/or a broadcasting-related information from an external broadcasting management server through a broadcasting channel. The broadcasting channel may include a satellite channel and a terrestrial channel.

The mobile communication module 522 may transmit/receive wireless signals to/from at least one of a base station, an external terminal, and/or a server on a mobile communication network established according to technical standards or communication methods for mobile communication (e.g., Global System for Mobile communication (GSM), Code Division Multi Access (CDMA), Code Division Multi Access 2000 (CDMA2000), Enhanced Voice-Data Optimized or Enhanced Voice-Data Only (EV-DO), Wideband CDMA (WCDMA), High Speed Downlink Packet Access (HSDPA), High Speed Uplink Packet Access (HSUPA), Long Term Evolution (LTE), Long Term Evolution-Advanced (LTE-A), etc.). The wireless signal may include a variety of data according to a voice call signal, a video call signal, and/or character/multimedia message transmission and reception.

The wireless Internet module 523 represents a module for wireless Internet access. The wireless Internet module 523 may be configured to transmit/receive wireless signals to/from a communication network according to wireless Internet technologies. The wireless Internet technologies may include, for example, Wireless LAN (WLAN), Wireless-Fidelity (Wi-Fi), Wi-Fi Direct, Digital Living Network Alliance (DLNA), etc.

The near field communication module 524 may be used for short range communication, and may support near field communication by using at least one of Bluetooth™, Radio Frequency Identification (RFID), Infrared Data Association (IrDA), Ultra Wideband (UWB), ZigBee, Near Field Communication (NFC), Wi-Fi, Wi-Fi Direct, Wireless Universal Serial Bus (USB) technologies, etc. The near field communication module 524 may support wireless communication between the electronic device 1 and a wireless communication system, between the electronic device 1 and another electronic device, or between networks in which the electronic device 1 and another electronic device (or an external server) are located, through wireless area networks. The wireless area networks may be wireless personal area networks. Another electronic device may be a wearable device that may exchange data with the electronic device 1 (or may be interlocked with the electronic device 1).

The position information module 525 may be a module for obtaining the position (or current position) of the electronic device 1, and representative examples of the position information module 525 may be a global positioning system (GPS) module or a Wi-Fi module. For example, if using the GPS module, the electronic device 1 may obtain the position of the electronic device 1 by using a signal sent from a GPS satellite. In addition, if using the Wi-Fi module, the electronic device 1 may obtain the position of the electronic device 1 based on information of wireless access point (AP) that transmits or receives a wireless signal to or from the Wi-Fi module. The position information module 525 that is a module used to obtain the position (or current position) of the electronic device 1 is not limited to a module that directly calculates or obtains the position of the electronic device 1.

The input 530 includes an image input, such as the camera device 531 for image signal input, a sound input, such as a microphone, for sound signal input, and an input device 533 for receiving information from the user.

The camera device 531 may process an image frame, such as a still image or a moving image obtained by the image sensor in a video call mode or an image-capturing mode. The processed image frame may be displayed on the display panel 10 or stored in the memory 570.

The microphone 532 may process an external sound signal with electrical voice data. The processed voice data may be variously utilized according to functions being performed (or an application being executed) in the electronic device 1. Various noise removal algorithms for removing noise, which is generated if an external sound signal is received, may be implemented in the microphone 532.

The main processor 510 may control the operation of the electronic device 1 to correspond to information input through the input device 533. The input device 533 may include a mechanical input, such as a button located at the rear surface or the side surface of the electronic device 1, a dome switch, a jog wheel, a jog switch, or the like, or a touch input. The touch input may be formed of a touch screen layer of the display panel.

The sensor 540 may include one or more sensors that sense at least one of information in the electronic device 1, peripheral environment information surrounding the electronic device 1, and/or user information, and that generate a sensing signal corresponding to the information. The main processor 510 may control driving or operation of the electronic device 1, or may perform data processing, functions, or operations related to an application installed at the electronic device 1. The sensor 540 may include at least one of a proximity sensor, an illumination sensor, an acceleration sensor, a magnetic sensor, a gravity (G)-sensor, a gyroscope sensor, a motion sensor, an RGB sensor, an infrared (IR) sensor, a finger scan sensor, an ultrasonic sensor, an optical sensor, a battery gauge, an environment sensor (e.g., a barometer, a humidity meter, a thermometer, a radioactive sensor, a thermal detection sensor, a gas detection sensor, etc.), and/or a chemical sensor (e.g., an electronic nose, a healthcare sensor, a biometric sensor, etc.).

The proximity sensor refers to a sensor that detects whether or not an object approaching a corresponding detection surface or an object in the vicinity by using the force of an electronic system or infrared rays without mechanical contact. Examples of proximity sensors include permeable optical photosensitive sensors, direct reflective photoelectric sensors, mirror reflective photoelectric sensors, high-frequency oscillation proximity sensors, capacitive type proximity sensors, magnetic type proximity sensors, and/or infrared ray proximity sensors. The proximity sensor may detect proximity touch patterns, such as a proximity touch distance, a proximity touch speed, a proximity touch time, a proximity touch position, and/or a proximity touch movement state in addition to a proximity touch. The main processor 510 may process data (or information) corresponding to proximity touch operations and/or proximity touch patterns detected by the proximity sensor, and may control visual information corresponding to the processed data to be displayed on the display panel 10.

The ultrasonic sensor may recognize position information of an object by using ultrasonic waves. The main processor 510 may calculate the position of the object through information detected by an optical sensor and a plurality of ultrasonic sensors. Because the speed of light and the speed of ultrasonic waves are different from each other, the position of the object may be calculated by using time at which light reaches the optical sensor and by using time at which ultrasonic waves reach the ultrasonic sensor.

The output 550 that is used to generate an output associated with a sight sense, an auditory sense, or a tactile sense, etc., and may include at least one of the display panel 10, the sound output 551, a haptic module 552, and/or a light output 553.

The display panel 10 may display (output) information processed by the electronic device 1. For example, the display panel 10 may display an execution screen information of the application driven by the electronic device 1, or user interface (UI), or graphic user interface (GUI) information according to the execution screen information. The display panel 10 may include a display layer for displaying an image and a touch screen layer for sensing the user's touch input. Thus, the display panel 10 may function as one of the input device 533 for providing an input interface between the electronic device 1 and the user, and may concurrently or substantially simultaneously may function as one of the output 550 for providing an output interface between the electronic device 1 and the user.

The sound output 551 may output sound data that is received from the wireless communicator 520 or that is stored in the memory 570 in a call signal reception mode, a call mode, a recording mode, a voice recognition mode, a broadcasting reception mode, or the like. The sound output 551 may output a sound signal related to the function (e.g., a call signal receiving sound, a message receiving sound, etc.) performed by the electronic device 1. The sound output 551 may include a receiver and a speaker. At least one of the receiver and/or the speaker may be a sound-generating device that is attached to a lower portion of the display panel 10 and that vibrates the display panel 10 to output sound. The sound-generating device may be a piezoelectric element or a piezoelectric actuator that contracts and expands in response to an electrical signal, or an exciter that generates magnetism by using a voice coil to vibrate the display panel 10.

The haptic module 552 may generate various tactile effects that the user may feel. The haptic module 552 may provide vibration to the user as the tactile effects. The strength and pattern of vibration generated by the haptic module 552 may be controlled by a user's selection or by a setting of the main processor 510. For example, the haptic module 552 may synthesize and output different vibrations, or may sequentially output them. In addition to vibration, the haptic module 552 may generate various tactile effects, such as the effects by a pin array that moves vertically with respect to the contacted skin surface, the blowing force or absorptive force of air through a nozzle or suction port, rubbing against the skin surface, contact with an electrode, stimulus by an electrostatic force, etc., and effects by reproducing cool and warm sensations by using elements capable of absorbing heat or generating heat. The haptic module 552 may be configured to not only transmit a tactile effect through direct contact, but also to allow the user to feel a tactile effect through muscle sense, such as a finger or an arm.

The light output 553 may output a signal for notifying occurrence of an event using light from a light source. Examples of events occurring in the electronic device 1 may include message reception, call signal reception, missed calls, alarms, schedule notifications, e-mail reception, and information reception through applications. The signal output by the light output 553 may be implemented as the electronic device 1 emits light of a single color or of multiple colors toward the front or rear surface. Signal output may be terminated if the electronic device 1 senses the user's event confirmation.

The interface 560 functions as a path with various types of external devices connected to the electronic device 1. The interface 560 may include at least one of a wired/wireless headset port, an external charger port, a wired/wireless data port, a memory card port, a port connecting a device having an identification module, an audio input/output (I/O) port, a video I/O port, and/or an earphone port. The electronic device 1 may perform proper control related to a connected external device in response to the external device connected to the interface 560.

The memory 570 may store data supporting various functions of the electronic device 1. The memory 570 may store a plurality of applications (application programs) driven in the electronic device 1, and may store data and commands for an operation of the electronic device 1. At least a portion of the plurality of applications may be downloaded from an external server through wireless communication. The memory 570 may store an application for the operation of the main processor 510, and may temporarily store input/output data, for example, data, such as phone book, messages, still images, moving images, and the like. In addition, the memory 570 may store haptic data for vibrations of various patterns provided to the haptic module 552, and may store sound data related to various sounds provided to the sound output 551.

The memory 570 may include a storage medium of at least one type of a flash memory type, a hard disk type, a solid state disk (SSD) type, a silicon disk drive (SDD) type, a multimedia card micro type, card type memory (e.g., a secure digital (SD) or extreme digital (XD) memory etc.), random access memory (RAM), static random access memory (SRAM), read-only memory (ROM), electrically erasable programmable read-only memory (EEPROM), programmable read-only memory (PROM)), a magnetic memory, a magnetic disk, and an optical disk.

The power supply 580 may receive external power and internal power under the control of the main processor 510, and may supply power to each component included in the electronic device 1. The power supply 580 may include a battery 80. In addition, the power supply 580 may include a connection port. The connection port may be configured as an example of the interface 560 to which an external charger, which is for supplying power for charging of the battery, is electrically connected. Alternatively, the power supply 580 may be configured to charge the battery 80 not by using the connection port, but instead by using a wireless method. The battery 80 may receive power from an external wireless power transmission device by using at least one of an inductive coupling method based on a magnetic induction phenomenon and/or a magnetic resonance coupling method based on electromagnetic resonance. The battery 80 may be located not to overlap the main circuit board 50 in a third direction (z direction). The battery 80 may overlap the battery hole BH of the bracket 60.

The lower cover 90 may be located under the main circuit board 50 and the battery 80. The lower cover 90 may be fastened and fixed to the bracket 60. The lower cover 90 may constitute the exterior of a lower surface of the electronic device 1. The lower cover 90 may include plastic, metal, or both plastic and metal.

A second camera hole CMH2, through which a lower surface of the camera device 531 is exposed, may be formed in the lower cover 90. The position of the camera device 531, and positions of the first and second camera holes CMH1 and CMH2 corresponding to the camera device 531, are not limited to the one or more embodiments corresponding to FIGS. 1 and 2, but instead may be variously changed.

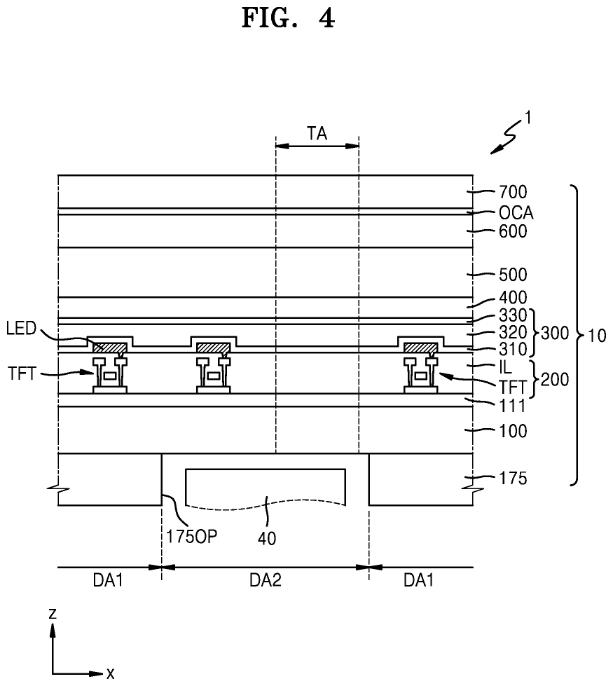

FIG. 4 is a cross-sectional view illustrating a portion of an electronic device according to one or more embodiments.

Referring to FIG. 4, the electronic device 1 may include a display panel 10 and components 40 located under the display panel 10.

The display panel 10 may include a substrate 100, a display layer 200, an encapsulation layer 300, an input-sensing layer 400, an optical functional layer 500, and an antireflective layer 600, and may also include the window 700, which may be located on the antireflective layer 600 through an adhesive layer, such as an optical clear adhesive (OCA).

The substrate 100 may include glass or polymer resin. For example, the polymer resin may include polyethersulfone, polyacrylate, polyether imide, polyethylene naphthalate, polyethylene terephthalate, polyphenylene sulfide, polyarylate, polyimide, polycarbonate, or cellulose acetate propionate. The substrate 100 including the polymer resin may have flexible, rollable, or bendable characteristics. The substrate 100 may have a multi-layered structure including a layer including the above-described polymer resin and an inorganic layer.

The display layer 200 may include a display element layer including the LED as a display element, a circuit layer including a thin-film transistor (TFT) electrically connected to the LED, a buffer layer 111 between the substrate 100 and the circuit layer, and an insulating layer IL between the display element layer and the circuit layer. The TFT, and the LED electrically connected to the TFT, may be arranged in a first display area DA1 and in a second display area DA2, respectively.

The second display area DA2 may include at least one transmission area TA in which no TFT and no LED are arranged. Light emitted from the components 40 and/or light toward the components 40 may transmit through the transmission area TA.

The display layer 200 may be sealed by an encapsulation member. In some embodiments, the encapsulation member may include an encapsulation layer 300, as shown in FIG. 4. The encapsulation layer 300 may include at least one inorganic encapsulation layer and at least one organic encapsulation layer. In one or more embodiments, the encapsulation layer 300 may include first and second inorganic encapsulation layers 310 and 330 and an organic encapsulation layer 320 therebetween.

The input-sensing layer 400 may obtain coordinate information according to external input, for example, a touch event of an object, such as a finger or stylus pen. The input-sensing layer 400 may include a touch electrode and trace lines connected to the touch electrode. The input-sensing layer 400 may sense an external input by using a mutual cap method or a self-cap method.

The optical functional layer 500 may be configured to enhance light efficiency. For example, front light efficiency and/or side visibility of light emitted from the LED may be improved.

The antireflective layer 600 may be configured to reduce reflectivity of light (external light) incident toward the display panel 10 from the outside. In some embodiments, the antireflective layer 600 may include an optical plate including a retarder and/or a polarizer. The antireflective layer 600 may include an opening that overlaps the transmission area TA.

In some embodiments, the antireflective layer 600 may include a filter plate including a black matrix and color filters. The filter plate may include color filters respectively arranged in sub-pixels, and a black matrix surrounding the color filters.

In some embodiments, the antireflective layer 600 may include a destructive interference structure. The destructive interference structure may include a first reflective layer and a second reflective layer, which are arranged in different layers. First reflected light and second reflected light, which are reflected from the first reflective layer and the second reflective layer, respectively, may be destructively interfered, and thus reflectivity of external light may be reduced.

The window 700 may be located on the antireflective layer 600, and may be coupled to the antireflective layer 600 through the adhesive layer, such as the OCA.

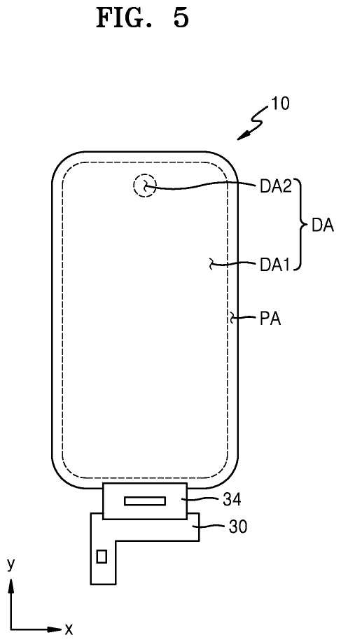

FIG. 5 is a plan view schematically illustrating a display panel according to one or more embodiments.

Referring to FIG. 5, the display area DA may be entirely surrounded by a peripheral area PA. A pad portion may be located in the peripheral area PA, and as shown in FIG. 5, the display circuit board 30 may be electrically connected to the pad portion of the peripheral area PA through the first soft film 34 in the peripheral area PA.

The display area DA may include a first display area DA1 and a second display area DA2. The second display area DA2 may be a kind of component area in which the components are located, as described above with reference to FIG. 4.

The second display area DA2 may be inside the first display area DA1, and may be entirely surrounded by the first display area DA1 (e.g., in plan view). The second display area DA2 may have a circular shape in a plan view. Alternatively, the second display area DA2 may have a polygonal shape, such as an oval shape or a rectangular shape.

The second display area DA2 may be in the middle of an upper side of the display area DA in a plan view, as shown in FIG. 5. In one or more other embodiments, the second display area DA2 may be in various positions, such as where the second display area DA2 is at a right upper side or in the middle of the display area DA in a plan view.

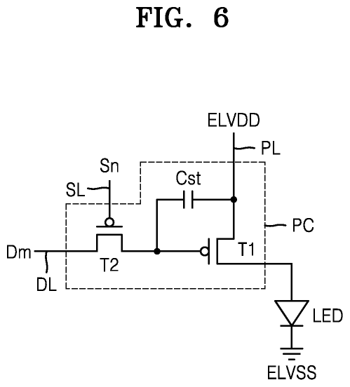

FIG. 6 is a circuit diagram illustrating a sub-pixel circuit connected to each light-emitting diode of a display panel according to one or more embodiments.

Referring to FIG. 6, the LED may be electrically connected to the sub-pixel circuit PC. The sub-pixel circuit PC may include a first thin-film transistor T1, a second thin-film transistor T2, and a storage capacitor Cst.

The second thin-film transistor T2 may be a switching thin-film transistor, may be connected to the scan line SL and the data line DL, and may be configured to transmit a data voltage (or a data signal Dm) input from the data line DL in response to a switching voltage input from the scan line SL to the first thin-film transistor T1. The storage capacitor Cst may be connected to the second thin-film transistor T2 and the driving voltage line PL, and may store a voltage corresponding to a difference between a voltage transmitted from the second thin-film transistor T2 and a first power supply voltage ELVDD supplied to the driving voltage line PL.

The first thin-film transistor T1 may be a driving thin-film transistor, may be connected to the driving voltage line PL and to the storage capacitor Cst, and may control a driving current flowing through the LED from the driving voltage line PL in response to a voltage value stored in the storage capacitor Cst. The LED may emit light having corresponding luminance by using the driving current. A second electrode (e.g., a cathode) of the LED may receive a second power supply voltage ELVSS.

FIG. 6 illustrates the case where the sub-pixel circuit PC includes two thin-film transistors and one storage capacitor, and embodiments are not limited thereto. The number of thin-film transistors and the number of storage capacitors may be variously changed according to the design of the sub-pixel circuit PC. For example, the sub-pixel circuit PC may include three, four, five or more thin-film transistors.

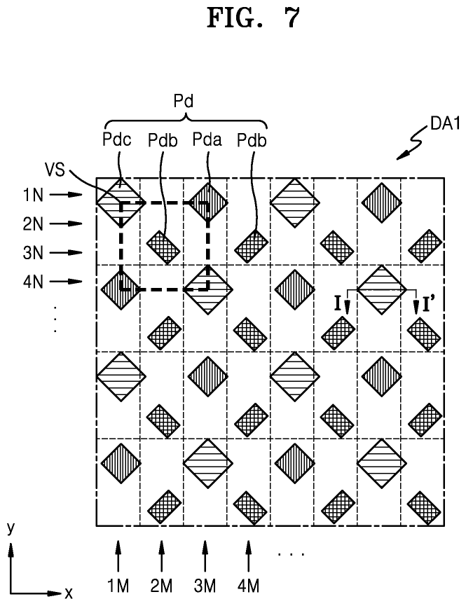

FIG. 7 is a plan view illustrating a portion of a first display area of a display panel according to one or more embodiments.

Referring to FIG. 7, display area sub-pixels Pd may be arranged in the first display area DA1. The display area sub-pixels Pd may include a first color sub-pixel Pda, a second color sub-pixel Pdb, and a third color sub-pixel Pdc. The first color, the second color, and the third color may be different respective colors, and for example, the first color may be red, the second color may be green, and the third color may be blue.

In some embodiments, the first color sub-pixel Pda, the second color sub-pixel Pdb, and the third color sub-pixel Pdc may be arranged in a PENTILE™ type (e.g., a RGBG matrix structure, a PENTILE™ matrix structure, a PENTILE™ structure, or an RGBG structure, PENTILE™ being a registered trademark of Samsung Display Co., Ltd., Republic of Korea).

A plurality of first color sub-pixels Pda and a plurality of third color sub-pixels Pdc may be alternately arranged in a first row 1N, and a plurality of second color sub-pixels Pdb may be arranged to be spaced apart from each other by a corresponding distance in an adjacent second row 2N. The plurality of third color sub-pixels Pdc and the plurality of first color sub-pixels Pda may be alternately arranged in an adjacent third row 3N, and the plurality of second color sub-pixels Pdb may be arranged to be spaced apart from each other by a corresponding distance in an adjacent fourth row 4N. The arrangement of these sub-pixels may be repeated up to a N-th row. In this case, the size (or width) of the third color sub-pixel Pdc and the first color sub-pixel Pda may be greater than the size (or width) of the second color sub-pixel Pdb.

A plurality of first color sub-pixels Pda and a plurality of third color sub-pixels Pb arranged in the first row 1N, and a plurality of second color sub-pixels Pdb arranged in the second row 2N, may cross one another, or may be offset from one another. Thus, a plurality of first color sub-pixels Pda and a plurality of third color sub-pixels Pdc may be alternately arranged in a first column 1M, and a plurality of second color sub-pixels Pdb may be arranged to be spaced apart from each other by a corresponding distance in an adjacent second column 2M. The plurality of third color sub-pixels Pdc and the plurality of first color sub-pixels Pda may be alternately arranged in an adjacent third column 3M, and the plurality of second color sub-pixels Pdb may be arranged to be spaced apart from each other by a corresponding distance in an adjacent fourth column 4M. The arrangement of these sub-pixels may be repeated up to a M-th column.

This sub-pixel arrangement structure may be expressed in another way. For example, the first color sub-pixels Pda may be arranged at first and third vertexes facing each other among vertexes of an imaginary rectangle VS, with the second color sub-pixels Pdb as the center point of the rectangle VS, and with the third color sub-pixels Pdc arranged at second and fourth vertexes that are the other/remaining vertexes. In this case, the imaginary rectangle VS may be modified in various shapes, such as rectangles, rhombuses, squares and the like.

This sub-pixel arrangement structure may be referred to as a PENTILE™ matrix structure or a PENTILE™ structure, and rendering driving for expressing color by sharing adjacent pixels may be applied, so that a suitably high resolution may be implemented with a relatively small number of sub-pixels.

FIG. 7 illustrates that display area sub-pixels Pd arranged in the first display area DA1 are arranged in a PENTILE™ matrix structure, but embodiments are not limited thereto. For example, the display area sub-pixels Pd, for example, the first color sub-pixels Pda, the second color sub-pixels Pdb, and the third color sub-pixels Pdc may be arranged in various shapes, such as a stripe structure, a mosaic arrangement structure, a delta arrangement structure, and the like.

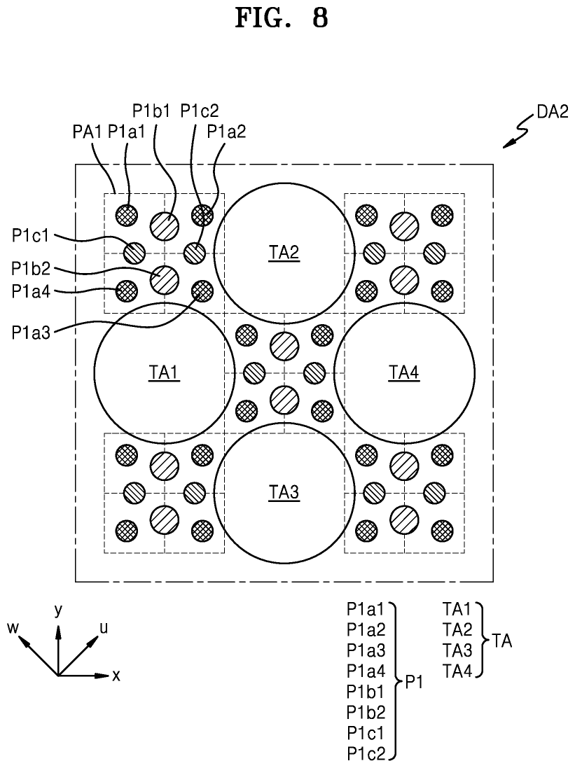

FIG. 8 is a plan view illustrating a portion of a second display area of a display panel according to one or more embodiments.

Referring to FIG. 8, the second display area DA2 may include a plurality of first pixel areas PA1, and a plurality of transmission areas TA in which the first pixel P1 is arranged. The plurality of transmission areas TA may include a first transmission area TA1, a second transmission area TA2, a third transmission area TA3, and a fourth transmission area TA4. The plurality of first pixel areas PA1 and the plurality of transmission areas TA may be alternately arranged. The first pixel areas PA1 may be surrounded by the plurality of transmission areas TA (e.g., in plan view). In detail, the plurality of first pixel areas PA1 may be surrounded by the first transmission area TA1, the second transmission area TA2, the third transmission area TA3, and the fourth transmission area TA4.

The first pixel area PA1 may have a rectangular shape in a plan view. In detail, the first pixel area PA1 may have a square shape. The transmission area TA may have a circular shape in a plan view. However, one or more embodiments are not limited thereto. At least a portion of the rectangular first pixel area PA1 and at least a portion of the circular transmission area TA may overlap each other.

The first pixel P1 may be arranged in the first pixel area PA1. The first pixel P1 may include four first sub-pixels P1a1, P1a2, P1a3, and P1a4, two second sub-pixels P1b1 and P1b2, and two third sub-pixels P1c1 and P1c2. The first sub-pixels P1a1, P1a2, P1a3, and P1a4 may emit green light, the second sub-pixels P1b1 and P1b2 may emit blue light, and the third sub-pixel P1c1 and P1c2 may emit red light. The number of first sub-pixels P1a1, P1a2, P1a3, and P1a4 may be greater than the number of second sub-pixels P1b1 and P1b2 and may be greater than the number of third sub-pixels P1c1 and P1c2. The number of first sub-pixels P1a1, P1a2, P1a3, and P1a4 that most affect perceptual image quality may be greater than the number of second sub-pixels P1b1 and P1b2 and greater than the number of third sub-pixels P1c1 and P1c2, such that perceptual image quality of the display area DA2 may be improved. In addition, the second sub-pixels P1b1 and P1b2 and the third sub-pixels P1c1 and P1c2, which are smaller in number than the first sub-pixels P1a1, P1a2, P1a3, and P1a4, may be located in the vicinity of the first sub-pixels P1a1, P1a2, P1a3, and P1a4.

In one or more embodiments, the first sub-pixels P1a1, P1a2, P1a3, and P1a4, the second sub-pixels P1b1 and P1b2, and the third sub-pixels P1c1 and P1c2 may have circular shapes. The first sub-pixels P1a1, P1a2, P1a3, and P1a4, the second sub-pixels P1b1 and P1b2, and the third sub-pixels P1c1 and P1c2 may have circular or curved shapes, so that reflectivity of external light incident from an opening of a pixel-defining layer to a display panel may be reduced, and visibility of the display apparatus may be improved.

In one or more embodiments, the four first sub-pixels P1a1, P1a2, P1a3, and P1a4 of the first pixel P1 may be spaced farther from the center of the first pixel area PA1 than the two second sub-pixels P1b1 and P1b2 and the two third sub-pixels P1c1 and P1c2. For example, the four first sub-pixels P1a1, P1a2, P1a3, and P1a4 of the first pixel P1 may be closer to edges of a rectangular shape of the first pixel area PA1 than the two second sub-pixels P1b1 and P1b2 and the two third sub-pixels P1c1 and P1c2.

Two second sub-pixels P1b1 and P1b2 may be spaced apart from each other in a second direction (e.g., a y direction or −y direction) based on the center of the rectangle shape of the first pixel area PA1. Two third sub-pixels P1c1 and P1c2 may be spaced apart from each other in a first direction (e.g., an x direction or −x direction) based on the center of the rectangle shape of the first pixel area PA1. Because four first sub-pixels P1a1, P1a2, P1a3, and P1a4 may be spaced apart from each other further than the second sub-pixels P1b1 and P1b2 and the third sub-pixels P1c1 and P1c2, and further from the center of the rectangular shape of the first pixel area PA1, the first sub-pixels P1a1, P1a2, P1a3, and P1a4 may be substantially uniformly distributed even in a narrow area in the diagonal direction between the plurality of transmission areas TA in the second display area DA2, so that transmittance in the second display area DA2 may be maintained and resolution may be improved.

For example, two first sub-pixels P1a1 and P1a3 may be spaced apart from each other in a first diagonal direction (e.g., a w direction or −w direction) based on the center of the rectangular shape of the first pixel area PA1. Two different first sub-pixels P1a2 and P1a4 may be spaced apart from each other in a second diagonal direction (e.g., a u direction or −u direction) based on the center of the rectangle shape of the first pixel area PA1.

Four first sub-pixels P1a1, P1a2, P1a3, and P1a4 may be electrically connected to the same signal line, and may concurrently or substantially simultaneously emit light. Two second sub-pixels P1b1 and P1b2 may be electrically connected to the same signal line, and may concurrently or substantially simultaneously emit light. Two third sub-pixels P1c1 and P1c2 may be electrically connected to the same signal line, and may concurrently or substantially simultaneously emit light. Each of the first sub-pixels P1a1, P1a2, P1a3, and P1a4, the second sub-pixels P1b1 and P1b2, and the third sub-pixels P1c1 and P1c2 may be connected to the same signal line, and may concurrently or substantially simultaneously emit light, so that transmittance in the second display area DA2 may be maintained, so that the number of sub-pixels in the first pixel area PA1 may be improved, and so that resolution in the second display area DA2 may be improved.

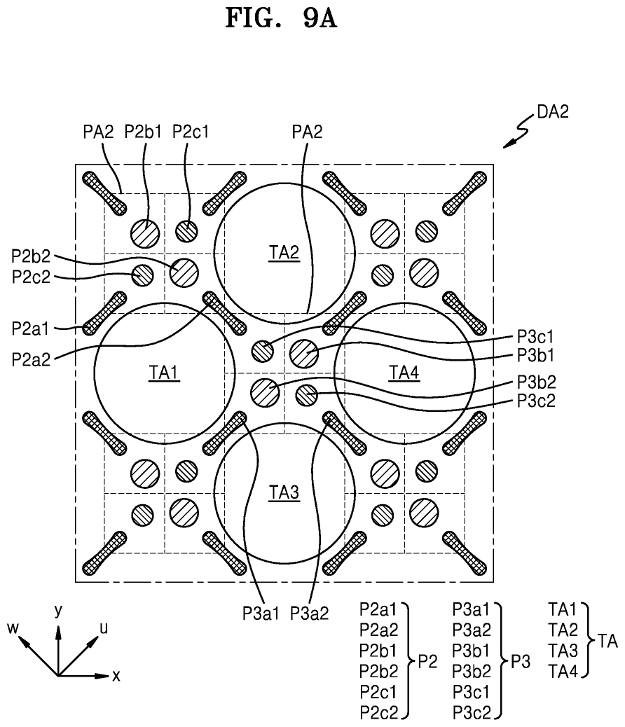

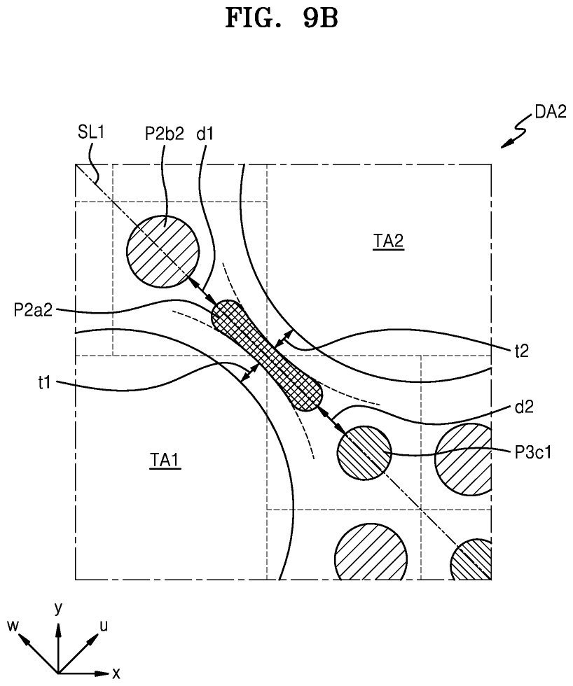

FIG. 9A is a plan view illustrating a portion of a second display area of a display panel according to one or more embodiments. FIG. 9B is an enlarged view schematically illustrating a portion of FIG. 9A.

Referring to FIGS. 9A and 9B, the second display area DA2 may include a plurality of second pixel areas PA2 in which a second pixel P2 and a third pixel P3 are arranged, and a plurality of transmission areas TA. The plurality of transmission areas TA may include a first transmission area TA1, a second transmission area TA2, a third transmission area TA3, and a fourth transmission area TA4. The plurality of second pixel areas PA2 and the plurality of transmission areas TA may be alternately arranged. The second pixel areas PA2 may be surrounded by the plurality of transmission areas TA. In detail, the second pixel areas PA2 may be surrounded by the first transmission area TA1, the second transmission area TA2, the third transmission area TA3, and the fourth transmission area TA4.

The second pixel area PA2 may have a rectangular shape in a plan view. In detail, the second pixel area PA2 may have a square shape. The transmission areas TA may have circular shapes in a plan view. However, one or more embodiments are not limited thereto. At least a portion of the rectangular second pixel area PA2 and at least a portion of the circular transmission areas TA may overlap each other.

The second pixel P2 and the third pixel P3 may be arranged in the second pixel area PA2. The second pixel P2 may include two first sub-pixels P2a1 and P2a2, two second sub-pixels P2b1 and P2b2, and two third sub-pixels P2c1 and P2c2. The third pixel P3 may include two first sub-pixels P3a1 and P3a2, two second sub-pixels P3b1 and P3b2, and two third sub-pixels P3c1 and P3c2. The first sub-pixels P2a1, P2a2, P3a1, and P3a2 may emit green light, and the second sub-pixels P2b1, P2b2, P3b1, and P3b2 may emit blue light, and the third sub-pixels P2c1, P2c2, P3c1, and P3c2 may emit red light.

In one or more embodiments, two first sub-pixels P2a1 and P2a2 of the second pixel P2 may be spaced apart from each other in the first direction (e.g., an x direction or −x direction) at edges of a lower portion of the rectangular shape of the second pixel area PA2 in a plan view. For example, one first sub-pixel P2a2 of the second pixel P2 may be arranged in a narrow area in a diagonal direction between the first transmission area TA1 and the second transmission area TA2. The first sub-pixels P2a1 and P2a2 may be arranged in a narrow area in the diagonal direction between the plurality of transmission areas TA so that transmittance in the second display area DA2 may be maintained, and so that resolution may be improved. Two second sub-pixels P2b1 and P2b2 of the second pixel P2 may be spaced apart from each other in the first diagonal direction (e.g., a w direction or −w direction) based on the center of the rectangular shape of the second pixel area PA2. Two third sub-pixels P2c1 and P2c2 of the second pixel P2 may be spaced apart from each other in a second diagonal direction (e.g., a u direction or −u direction) based on the center of the rectangular shape of the second pixel area PA2.

In one or more embodiments, at least a portion of a shape of the first sub-pixels P2a1 and P2a2 may be provided in an arc shape of a circle (e.g., an imaginary circle) having the same center as (e.g., being concentric with) a circle corresponding to a circular shape of an adjacent one of the transmission areas TA (e.g., an edge of the first sub-pixels P2a1 and P2a2 corresponding to the arc shape may have a same shortest distance to an edge of a circle corresponding to corresponding transmission area TA). For example, at least a portion of the shape of the first sub-pixel P2a2 of the second pixel P2 may be provided in an arc shape of a circle having the same center as that of the circular shape of the first transmission area TA1, and another portion of the shape of the first sub-pixel P2a2 of the second pixel P2 may be provided in an arc shape of a circle having the same center as that of a circular shape of the second transmission area TA2. At least a portion of the shape of the first sub-pixel P2a2 may be provided in an arc shape of a circle having the same center as that of circular shapes of the transmission areas TA1 and TA2, so that sub-pixels may be widely arranged even in a narrow area in a diagonal direction between the plurality of transmission areas TA, and so that resolution in the second display area DA2 may be improved.

In one or more embodiments, as shown in FIG. 9B, a shortest separation distance t1 between the first sub-pixel P2a2 of the second pixel P2 and the adjacent first transmission area TA1, and a shortest separation distance t2 between the first sub-pixel P2a2 of the second pixel P2 and the adjacent second transmission area TA2, may be substantially equal to each other.

In the design process of the display apparatus, a corresponding distance between an edge portion of the transmission area TA and an edge portion of the sub-pixel may be suitably secured such that a first electrode of the LED may be wider than the opening of the pixel-defining layer. A corresponding distance between the edge portion of the transmission area TA and the edge portion of the sub-pixel may be suitably secured so that the likelihood of defects may be reduced or prevented from occurring in the display apparatus due to moisture and oxygen permeating into the pixel-defining layer. The shortest separation distance t1 between the first sub-pixel P2a2 of the second pixel P2 and the adjacent first transmission area TA1 and the shortest separation distance t2 between the first sub-pixel P2a2 of the second pixel P2 and the adjacent second transmission area TA2 may be a corresponding distance between an edge portion of the transmission area TA and an edge portion of the sub-pixel so as to reduce or prevent the likelihood of defects of the display apparatus in the design process of the display apparatus.

In one or more embodiments, the second sub-pixels P2b1 and P2b2 and the third sub-pixels P2c1 and P2c2 may be provided in circular shapes. Portions other than a circular arc portion in the shape of the first sub-pixels P2a1 and P2a2 may also be provided in a curved shape. The first sub-pixels P1a1 and P1a2, the second sub-pixels P1b1 and P1b2, and the third sub-pixels P1c1 and P1c2 may have circular or curved shapes so that reflectivity of external light incident from the opening of the pixel-defining layer to a display panel may be reduced and visibility of the display apparatus may be improved.

In one or more embodiments, the center of the second sub-pixels P2b1 and P2b2 and the center of the third sub-pixels P2c1 and P2c2 may be located in the same line. A first imaginary line SL1 may extend in the first diagonal direction (e.g., a w direction or −w direction) while passing the center of the rectangular shape of the second pixel area PA2. For example, the center of the second sub-pixels P2b1 and P2b2 and the center of the third sub-pixels P2c1 and P2c2 may be located in the first imaginary line SL1. The center of the second sub-pixel P2b2 of the second pixel P2 and the center of the third sub-pixel P3c1 of the adjacent third pixel P3 may also be located in the first imaginary line SL1.

A shortest separation distance d1 between the first sub-pixel P2a2 of the second pixel P2 and the second sub-pixel P2b2 of the second pixel P2 and a shortest separation distance d2 between the first sub-pixel P2a2 of the second pixel and the third sub-pixel P3c1 of the third pixel P3 may be substantially equal to each other. Light-emitting materials of each of the first sub-pixels P2a1, P2a2, P3a1, and P3a2, the second sub-pixels P2b1, P2b2, P3b1, and P3b2, and the third sub-pixels P2c1, P2c2, P3c1, and P3c2 may be deposited on the display panel by using a fine metal mask (FMM). For each light-emitting material to be efficiently deposited on each sub-pixel by using a FMM process, a separation distance between sub-pixels may be suitably secured at a corresponding distance or more. The shortest separation distance d1 between the first sub-pixel P2a2 of the second pixel P2 and the adjacent second sub-pixel P2b2 of the second pixel P2, and the shortest separation distance d2 between the first sub-pixel P2a2 of the second pixel P2 and the third sub-pixel P3c1 of the adjacent third pixel P3, may be a corresponding distance that is suitable for the light-emitting material to be deposited by using the FMM process. The shortest separation distance d1 between the first sub-pixel P2a2 of the second pixel P2 and the adjacent second sub-pixel P2b2 of the second pixel P2, and the shortest separation distance d2 between the first sub-pixel P2a2 of the second pixel P2 and the adjacent third sub-pixel P3c1 of the third pixel P3, may suitably be substantially equal to each other as a corresponding distance suitable for the light-emitting material to be deposited by using the FMM process so that the sub-pixels occupy a wide area and are substantially uniformly distributed in a narrow area in the diagonal direction between the plurality of transmission areas TA, and thus resolution may be improved while maintaining the transmittance in the second display area DA2.

In addition, two first sub-pixels P1a1 and P1a2 of the second pixel P2 may be electrically connected to the same scan line, and may concurrently or substantially simultaneously emit light. Two second sub-pixels P1b1 and P1b2 of the second pixel P2 may be electrically connected to the same scan line, and may concurrently or substantially simultaneously emit light. Two third sub-pixels P1c1 and P1c2 of the second pixel P2 may be electrically connected to the same scan line, and may concurrently or substantially simultaneously emit light. Each of the first sub-pixels P1a1 and P1a2, the second sub-pixels P1b1 and P1b2, and the third sub-pixels P1c1 and P1c2 of the second pixel P2 may be connected to the same scan line, and may concurrently or substantially simultaneously emit light, so that transmittance in the second display area DA2 may be maintained, the number of sub-pixels in the second pixel area PA2 may be increased, and resolution in the second display area DA2 may be improved.

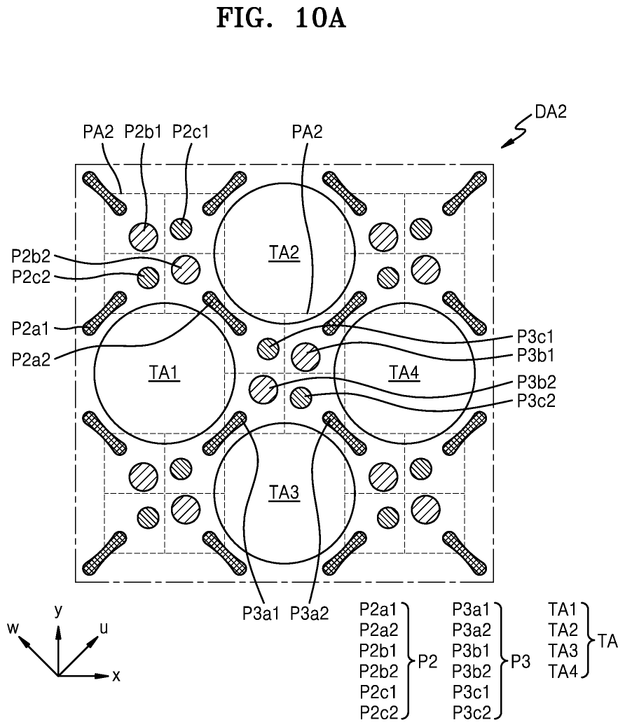

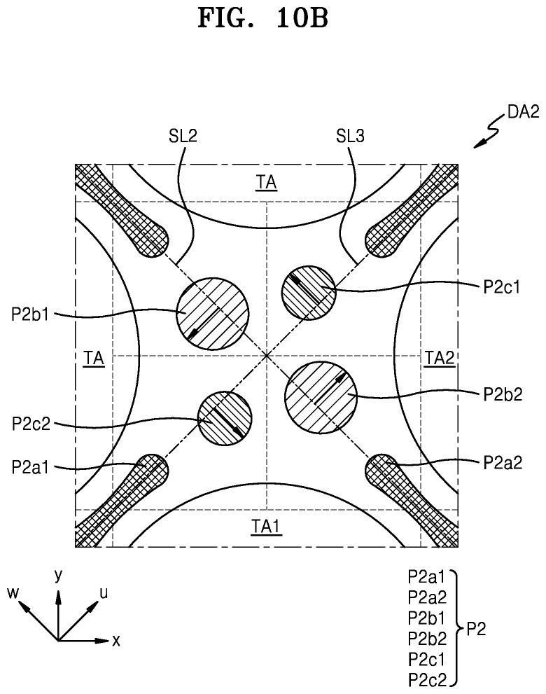

FIG. 10A is a plan view illustrating a portion of a second display area of a display panel according to one or more embodiments. FIG. 10B is an enlarged view schematically illustrating a portion of FIG. 10A.

Referring to FIGS. 10A and 10B, the second pixel P2 and the third pixel P3 may be arranged in the second display area DA2, and the transmission areas TA may be arranged to surround the second display area DA2. The second pixel P2 may include two first sub-pixels P2a1 and P2a2, two second sub-pixels P2b1 and P2b2, and two third sub-pixels P2c1 and P2c2. The first sub-pixels P2a1 and P2a2 may emit green light, and the second sub-pixels P2b1 and P2b2 may emit blue light, and the third sub-pixels P2c1 and P2c2 may emit red light.

Two first sub-pixels P2a1 and P2a2 of the second pixel P2 may be spaced apart from each other in the first direction (e.g., an x direction or −x direction) at edges of a lower portion of the rectangular shape of the second pixel area PA2 in a plan view. In a manner similar to that described above with respect to FIGS. 9A and 9B, at least a portion of a shape of the first sub-pixels P2a1 and P2a2 may be provided in an arc shape of a circle having the same center as that of a circular shape of the adjacent transmission area TA. For example, at least a portion of the shape of the first sub-pixel P2a2 of the second pixel P2 may be provided in an arc shape of a circle having the same center as that of the circular shape of the first transmission area TA1, and another portion of the shape of the first sub-pixel P2a2 of the second pixel P2 may be provided in an arc shape of a circle having the same center as that of a circular shape of the second transmission area TA2.

The second sub-pixels P2b1 and P2b2 and the third sub-pixels P3c1 and P3c2 may be respectively provided in circular shapes. Two second sub-pixels P2b1 and P2b2 of the second pixel P2 may be spaced apart from each other in the first diagonal direction (e.g., a w direction or −w direction) based on the center of the rectangular shape of the second pixel area PA2. Two third sub-pixels P2c1 and P2c2 of the second pixel P2 may be spaced apart from each other in a second diagonal direction (e.g., a u direction or −u direction) based on the center of the rectangular shape of the second pixel area PA2.

As shown in FIG. 10B, a second imaginary line SL2 may extend in the first diagonal direction (e.g., a w direction or −w direction) while passing through the center of the rectangular shape of the second pixel area PA2. For example, the second imaginary line SL2 may pass through the center of the rectangular shape of the second pixel area PA2, and may pass through edges or corners spaced apart from each other in the first diagonal direction (e.g., a w direction or −w direction). A third imaginary line SL3 may extend in the second diagonal direction (e.g., a u direction or −u direction) while passing through the center of the rectangular shape of the second pixel area PA2. For example, the third imaginary line SL3 may pass through the center of the rectangular shape of the second pixel area PA2 and through edges or corners spaced apart from each other in the second diagonal direction (e.g., a u direction or −u direction).

In one or more embodiments, the center of the second sub-pixels P2b1 and P2b2 of the second pixel P2 may be spaced apart from, or shifted from, the second imaginary line SL2. For example, the center of the second sub-pixels P2b1 and P2b2 of the second pixel P2 may not be located in the second imaginary line SL2. The center of the third sub-pixels P2c1 and P2c2 of the second pixel P2 may be spaced apart from the third imaginary line SL3. For example, the center of the third sub-pixels P2c1 and P2c2 of the second pixel P2 may not be located in the third imaginary line SL3. The centers of the second sub-pixels P2b1 and P2b2 of the second pixel P2 may be spaced apart from the second imaginary line SL2, and the centers of the third sub-pixels P2c1 and P2c2 of the second pixel P2 may be spaced apart from, or shifted from, the third imaginary line SL3, and the area occupied by the first sub-pixels P2a1 and P2a2 that most affect perceptual image quality may be wider.

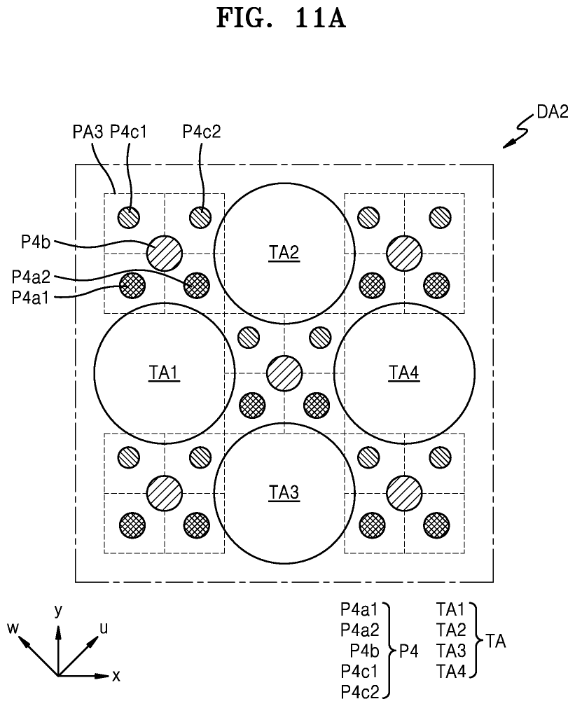

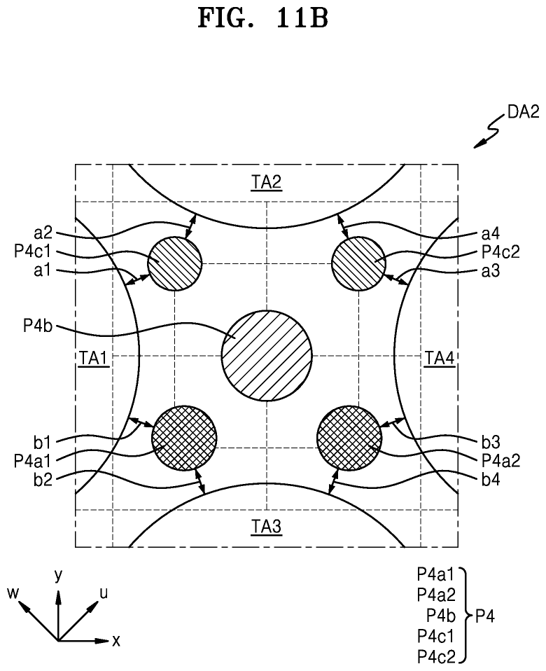

FIG. 11A is a plan view illustrating a portion of a second display area of a display panel according to one or more embodiments. FIG. 11B is an enlarged view schematically illustrating a portion of FIG. 11A.

Referring to FIGS. 11A and 11B, the second display area DA2 may include a plurality of third pixel areas PA3 in which the fourth pixel P4 is located, and a plurality of transmission areas TA. The plurality of third pixel areas PA3 may be surrounded by the plurality of transmission areas TA.

The third pixel area PA3 may have a rectangular shape in a plan view. In detail, the third pixel area PA3 may have a square shape. The transmission area TA may have a circular shape in a plan view.

The fourth pixel P4 may include two first sub-pixels P4a1 and P4a2, one second sub-pixel P4b, and two third sub-pixels P4c1 and P4c2. The first sub-pixels P4a1 and P4a2 may emit green light, and the second sub-pixel P4b may emit blue light, and the third sub-pixels P4c1 and P4c2 may emit red light. Two first sub-pixels P4a1 and P4a2 may be spaced apart from each other in a first direction (e.g., an x direction or −x direction) at a lower portion of the third pixel area PA3 based on the center of the rectangle shape of the third pixel area PA3. One second sub-pixel P4b may be arranged in the center of the rectangular shape of the third pixel area PA3. Two third sub-pixels P4c1 and P4c2 may be spaced apart from each other in a first direction (e.g., an x direction or −x direction) at an upper portion of the third pixel area PA3 based on the center of the rectangle shape of the third pixel area PA3.

In one or more embodiments, as shown in FIG. 11B, a shortest separation distance a1 between the third sub-pixel P4c1 of the fourth pixel P4 and the adjacent first transmission area TA1, and a shortest separation distance a2 between the third sub-pixel P4c1 of the fourth pixel P4 and the adjacent second transmission area TA2, may be substantially equal to each other. In addition, a shortest separation distance a4 between the third sub-pixel P4c2 of the fourth pixel P4 and the adjacent second transmission area TA2, and a shortest separation distance a3 between the third sub-pixel P4c2 of the fourth pixel P4 and the adjacent fourth transmission area TA4, may be substantially equal to each other.

In the design process of the display apparatus, a corresponding distance between an edge portion of the transmission area TA and an edge portion of the sub-pixel may be suitably secured such that a first electrode of the LED may be wider than the opening of the pixel-defining layer. A corresponding distance between the edge portion of the transmission area TA and the edge portion of the sub-pixel may be suitably secured so that the likelihood of defects may be reduced or prevented from occurring in the display apparatus due to moisture and oxygen permeating into the pixel-defining layer. The shortest separation distance a1 between the third sub-pixel P4c1 and the adjacent first transmission area TA1, and the shortest separation distance a2 between the third sub-pixel P4c1 and the adjacent second transmission area TA2, may be a distance between the edge portion of a corresponding transmission area TA and the edge portion of the third sub-pixel P4c1, and may reduce or prevent the likelihood of defects in the display apparatus in the design process. In addition, a shortest separation distance a4 between the third sub-pixel P4c2 and the adjacent second transmission area TA2, and a shortest separation distance a3 between the third sub-pixel P4c2 and the adjacent fourth transmission area TA4, may be a distance between the edge portion of a corresponding transmission area TA and the edge portion of the third sub-pixel P4c2 to reduce or prevent defects in the display apparatus in the design process.

The shortest separation distance a1 between the third sub-pixel P4c1 and the adjacent first transmission area TA1, the shortest separation distance a2 between the third sub-pixel P4c1 and the adjacent second transmission area TA2, the shortest separation distance a4 between the third sub-pixel P4c2 and the adjacent second transmission area TA2, and the shortest separation distance a3 between the third sub-pixel P4c2 and the adjacent fourth transmission area TA4, may be a corresponding distance that is suitable for the design process so that the areas of light-emitting areas of the first sub-pixels P4a1 and P4a2, the second sub-pixel P4b, and the third sub-pixels P4c1 and P4c2 of the fourth pixel P4 may be increased, and so that resolution in the second display area DA may be improved.

Similarly, a shortest separation distance b1 between the first sub-pixel P4a1 of the fourth pixel P4 and the first transmission area TA1, and a shortest separation distance b2 between the first sub-pixel P4a1 of the fourth pixel P4 and the third transmission area TA3, may be substantially equal to each other as a corresponding distance between the edge portion of the first sub-pixel P4a1 and the edge portion of the corresponding transmission area, which is suitable to reduce or prevent defects of the display apparatus. In addition, a shortest separation distance b4 between the first sub-pixel P4a2 of the fourth pixel P4 and the third transmission area TA3, and a shortest separation distance b3 between the first sub-pixel P4a2 of the fourth pixel P4 and the fourth transmission area TA4, may be substantially equal to each other as a corresponding distance between the edge portion of the first sub-pixel P4a2 and the edge portion of the corresponding transmission area, which is suitable to reduce or prevent defects of the display apparatus. Consequently, respective shortest separation distances between the first sub-pixels P4a1 and P4a2 and the third sub-pixels P4c1 and P4c2 of the fourth pixel P4 and the respective adjacent transmission areas TA (e.g., distances a1, a2, a3, a4, b1, b2, b3, and b4) may be substantially equal to each other.

Two first sub-pixels P4a1 and P4a2 may be electrically connected to the same signal line, and may concurrently or substantially simultaneously emit light. Two third sub-pixels P4c1 and P4c2 may be electrically connected to the same signal line, and may concurrently or substantially simultaneously emit light. The first sub-pixels P4a1 and P4a2 and the third sub-pixels P4c1 and P4c2 may be connected to the same signal line to concurrently or substantially simultaneously emit light so that transmittance in the second display area DA2 may be maintained, so that the number of sub-pixels in the third pixel area PA3 may be increased, and so that resolution in the second display area DA2 may be improved.

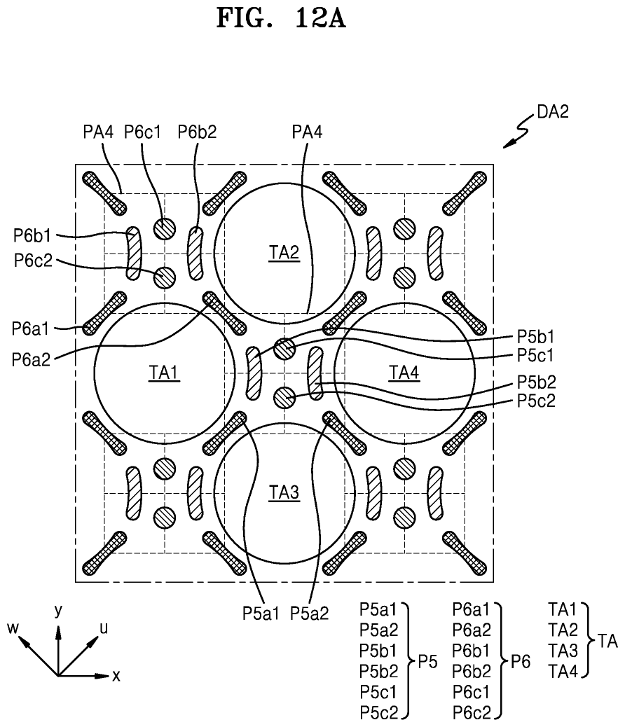

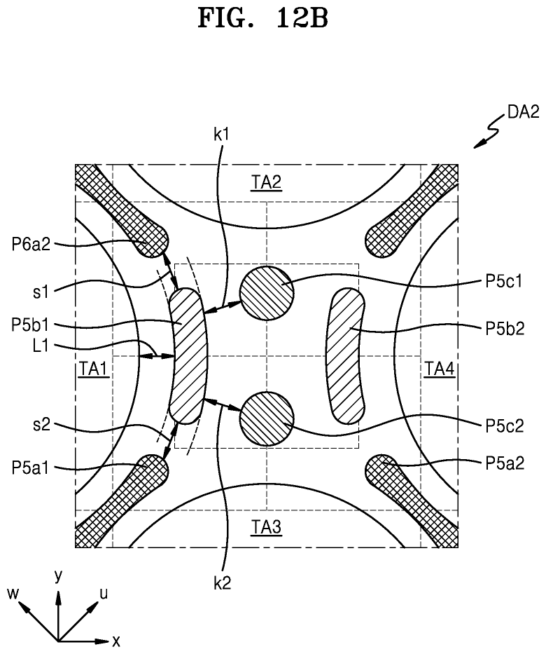

FIG. 12A is a plan view illustrating a portion of a second display area of a display panel according to one or more embodiments. FIG. 12B is an enlarged view schematically illustrating a portion of FIG. 12A.

Referring to FIGS. 12A and 12B, the second display area DA2 may include a plurality of fourth pixel areas PA4 in which a fifth pixel P5 and a sixth pixel P6 are arranged, and a plurality of transmission areas TA. The plurality of fourth pixel areas PA4 and the plurality of transmission areas TA may be alternately arranged. The fourth pixel areas PA4 may be surrounded by the plurality of transmission areas TA.

The fourth pixel area PA4 may have a rectangular shape in a plan view. In detail, the fourth pixel area PA4 may have a square or rectangular shape. The transmission area TA may have a circular shape in a plan view. However, one or more embodiments are not limited thereto.

The fifth pixel P5 located in the fourth pixel area PA4 may include two first sub-pixels P5a1 and P5a2, two second sub-pixels P5b1 and P5b2, and two third sub-pixels P5c1 and P5c2. Two first sub-pixels P5a1 and P5a2 of the fifth pixel P5 may be spaced apart from each other in the first direction (e.g., an x direction or −x direction) at edges of a lower portion of the rectangular shape of the fourth pixel area PA4 in a plan view. For example, one first sub-pixel P5a1 of the fifth pixel P5 may be arranged in a narrow area in a diagonal direction between the first transmission area TA1 and the third transmission area TA3.

In a manner similar to that described above with respect to FIGS. 9A, 9B, 10A, and 10B, at least a portion of a shape of the first sub-pixels P5a1 and P5a2 of the fifth pixel P5 may be provided in an arc shape of a circle having the same center as that of a circular shape of the adjacent transmission area TA. For example, at least a portion of the shape of the first sub-pixel P5a1 of the fifth pixel P5 may be provided in an arc shape of a circle having the same center as that of the circular shape of the first transmission area TA1, and another portion of the shape of the first sub-pixel P5a1 of the fifth pixel P5 may be provided in an arc shape of a circle having the same center as that of a circular shape of the third transmission area TA3. At least a portion of the shape of the first sub-pixel P5a1 may be provided in an arc shape of a circle having the same center as that of circular shapes of the transmission areas TA1 and TA3 so that sub-pixels may be widely arranged even in a narrow area in a diagonal direction between the plurality of transmission areas TA, and so that resolution in the second display area DA2 may be improved.

Two third sub-pixels P5c1 and P5c2 of the fifth pixel P5 may be spaced apart from each other in a second direction (e.g., a y direction or −y direction) based on the center of the rectangle shape of the fourth pixel area PA4. The third sub-pixels P5c1 and P5c2 may be provided in a circular shape. However, one or more embodiments are not limited thereto.

Two second sub-pixels P5b1 and P5b2 of the fifth pixel P5 may be spaced apart from each other in a first direction (e.g., an x direction or −x direction) based on the center of the rectangle shape of the second display area DA2. At least a portion of a shape of the second sub-pixel P5b1 of the fifth pixel P5 may be provided in an arc shape of a circle having the same center as that of a circular shape of the first transmission area TA1. At least a portion of a shape of the second sub-pixel P5b1 of the fifth pixel P5 may be provided in an arc shape of a circle having the same center as that of a circular shape of the first transmission area TA1.

A shortest separation distance L1 between the first transmission area TA1 and the second sub-pixel P5b1 of the adjacent fifth pixel P5 may be suitably secured at a corresponding distance or more. In the design process of the display apparatus, a corresponding distance between an edge portion of the transmission area TA and an edge portion of the sub-pixel may be suitably secured such that a first electrode of the LED may be wider than the opening of the pixel-defining layer. A corresponding distance between the edge portion of the transmission area TA and the edge portion of the sub-pixel may be suitably secured so that the likelihood of defects may be reduced or prevented from occurring in the display apparatus due to moisture and oxygen permeating into the pixel-defining layer.

As can be seen in FIG. 12b, a shortest separation distance s1 between the second sub-pixel P5b1 of the fifth pixel P5 and the first sub-pixel P6a2 of the adjacent sixth pixel P6, and a shortest separation distance s2 between the second sub-pixel P5b1 of the fifth pixel P5 and the first sub-pixel P5a1 of the fifth pixel P5, may be substantially equal to each other. A light-emitting material of each of the first sub-pixels P5a1 and P5a2, the second sub-pixels P5b1 and P5b2, and the third sub-pixels P5c1 and P5c2 may be deposited on the display panel by using the FMM. For each light-emitting material, to be efficiently deposited on each sub-pixel by using a FMM process, a separation distance between sub-pixels may suitably be secured at a corresponding distance or more. The shortest separation distance s1 between the second sub-pixel P5b1 of the fifth pixel P5 and the first sub-pixel P6a2 of the adjacent sixth pixel P6, and the shortest separation distance s2 between the second sub-pixel P5b1 of the fifth pixel P5 and the first sub-pixel P5a1 of the fifth pixel P5, may be corresponding distances suitable for the light-emitting material to be deposited by using the FMM process. The shortest separation distance s1 between the second sub-pixel P5b1 of the fifth pixel P5 and the first sub-pixel P6a2 of the adjacent sixth pixel P6, and the shortest separation distance s2 between the second sub-pixel P5b1 of the fifth pixel P5 and the first sub-pixel P5a1 of the fifth pixel P5, may be suitably equal to each other as a corresponding distance that is suitable for the light-emitting material to be deposited by using the FMM process so that the sub-pixels occupy a wide area and are substantially uniformly distributed in a narrow area in the diagonal direction between the plurality of transmission areas TA, and thus resolution may be improved while maintaining the transmittance in the second display area DA2.

Similarly, a shortest separation distance k1 between the second sub-pixel P5b1 of the fifth pixel P5 and the adjacent third sub-pixel P5c1 of the fifth pixel P5, and a shortest separation distance k2 between the second sub-pixel P5b1 of the fifth pixel P5 and the adjacent third sub-pixel P5c2 of the fifth pixel P5, may be substantially equal to each other. The shortest separation distance k1 between the second sub-pixel P5b1 of the fifth pixel P5 and the adjacent third sub-pixel P5c1 of the fifth pixel P5, and the shortest separation distance k2 between the second sub-pixel P5b1 of the fifth pixel P5 and the adjacent third sub-pixel P5c2 of the fifth pixel P5, may be suitably equal to each other as a corresponding distance suitable for the light-emitting material to be deposited by using the FMM process so that the sub-pixels occupy a wide area and are substantially uniformly distributed in a narrow area in the diagonal direction between the plurality of transmission areas TA, and thus resolution may be improved while maintaining the transmittance in the second display area DA2.

Consequently, the shortest separation distance s1 between the second sub-pixel P5b1 of the fifth pixel P5 and the first sub-pixel P6a2 of the adjacent sixth pixel P6, the shortest separation distance s2 between the second sub-pixel P5b1 of the fifth pixel P5 and the adjacent first sub-pixel P5a1 of the fifth pixel P5, the shortest separation distance k1 between the second sub-pixel P5b1 of the fifth pixel P5 and the adjacent third sub-pixel P5c1 of the fifth pixel P5, and the shortest separation distance k2 between the second sub-pixel P5b1 of the fifth pixel P5 and the adjacent third sub-pixel P5c2 of the fifth pixel P5, may be substantially equal to each other.

At least a portion of the shape of the second sub-pixel P5b1 of the fifth pixel P5 may be provided in an arc shape of a circle having the same center as the circular shape of the transmission area, so that a corresponding distance between the second sub-pixel P5b1 and the edge of the first transmission area TA1 for reducing or preventing defects of the display apparatus in the design process may be secured and a corresponding distance at which the light-emitting material is effectively deposited on the panel in the FMM process may be secured, so that the area occupied by the second sub-pixel P5b1 in the second display area DA2 may be increased, so that transmittance in the second display area DA2 may be maintained, and so that resolution may be improved.

In embodiments of the disclosure, a corresponding distance between the sub-pixel and the edge of the transmission area TA suitable in the design process may be secured, and a corresponding distance between the pixels to efficiently deposit the light-emitting material on the panel in the FMM process may be secured, so that the area occupied by sub-pixels in the second display area DA2 may be increased, so that transmittance in the second display area DA2 may be maintained, and so that resolution may be improved.

According to embodiments, a display apparatus in which a high-quality image may be implemented, and in which resolution may be improved, may be provided. These aspects are illustrative, and the scope of the present disclosure is not limited thereto.

It should be understood that embodiments described herein should be considered in a descriptive sense only and not for purposes of limitation. Descriptions of aspects within each embodiment should typically be considered as available for other similar aspects in other embodiments. While one or more embodiments have been described with reference to the figures, it will be understood by those of ordinary skill in the art that various changes in form and details may be made therein without departing from the spirit and scope as defined by the following claims, with functional equivalents thereof to be included therein.

1 what is claimed is:

1. A display apparatus comprising:
a first display area in which sub-pixels are arranged; and
a second display area adjacent to the first display area, and comprising:
a second pixel area in which there is a second pixel having a rectangular shape in plan view, and comprising two first sub-pixels spaced apart from each other in a first direction at a lower portion of the second pixel area, two second sub-pixels, and two third sub-pixels are arranged; and
transmission areas surrounding the second pixel area,
wherein a portion of one of the first sub-pixels has an arc shape of a circle having a same center as a circular shape of an adjacent one of the transmission areas.

2. The display apparatus of claim 1, wherein the two second sub-pixels are spaced apart in a first diagonal direction and spaced from a center of the second pixel area.

3. The display apparatus of claim 2, wherein the two third sub-pixels are spaced apart in a second diagonal direction crossing the first diagonal direction and spaced from the center of the second pixel area.

4. The display apparatus of claim 1, wherein a shortest distance between one of the first sub-pixels and an adjacent first transmission area of the transmission areas, and a shortest distance between the one of the first sub-pixels and an adjacent second transmission area of the transmission areas, are substantially equal.

5. The display apparatus of claim 1, wherein a center of one of the second sub-pixels, a center of one of the third sub-pixels, and a center of the second pixel area are in a same line.

6. The display apparatus of claim 1, wherein centers of the second sub-pixels are shifted from a line extending in a first diagonal direction while passing through the second pixel area.

7. The display apparatus of claim 6, wherein centers of the third sub-pixels are shifted from a line extending in a second diagonal direction crossing the first diagonal direction and passing through the center of the second pixel area.

8. The display apparatus of claim 1, wherein a portion of one of the second sub-pixels has an arc shape of a circle having the same center as the circular shape of the adjacent one of the transmission areas.

9. The display apparatus of claim 8, wherein the second sub-pixels are spaced apart in the first direction and spaced from a center of the second display area.

10. The display apparatus of claim 8, wherein the second sub-pixels comprise a (2^{nd}-1) sub-pixel and a (2^{nd}-2) sub-pixel, and
wherein a shortest distance between the (2^{nd}-1) sub-pixel and an adjacent one of the first sub-pixels, and a shortest distance between the (2^{nd}-1) sub-pixel and a first sub-pixel of an adjacent third pixel, are substantially equal to each other.

11. The display apparatus of claim 8, wherein a shortest distance between the one of the second sub-pixels and the adjacent one of the first sub-pixels, and a shortest distance between the one of the second sub-pixels and another adjacent first sub-pixel, are substantially equal to each other.

12. A display apparatus comprising:
a first display area in which sub-pixels are arranged; and
a second display area adjacent to the first display area, and comprising:
a first pixel area in which there is a first pixel having a rectangular shape in a plan view, and comprising four first sub-pixels, two second sub-pixels, and two third sub-pixels; and
transmission areas surrounding the first pixel area,
wherein the first sub-pixels are spaced from a center of the first pixel area further than the second sub-pixels and the third sub-pixels.

13. The display apparatus of claim 12, wherein the first sub-pixels, the second sub-pixels, and the third sub-pixels have respective circular shapes.

14. The display apparatus of claim 12, wherein the transmission areas have respective circular shapes.

15. The display apparatus of claim 13, wherein a portion of the first pixel area and a portion of one of the transmission areas overlap.

16. The display apparatus of claim 12, wherein two of the first sub-pixels are spaced from each other in a first diagonal direction and are spaced from the center of the first pixel area, and
wherein two others of the first sub-pixels are spaced from each other in a second diagonal direction crossing the first diagonal direction and are spaced from the center of the first pixel area.

17. The display apparatus of claim 12, wherein the first sub-pixels are configured to emit green light, the second sub-pixels are configured to emit blue light, and the third sub-pixels are configured to emit red light.

18. The display apparatus of claim 12, wherein the first sub-pixels are electrically connected to a same signal line, and are configured to emit light concurrently or substantially simultaneously.

19. The display apparatus of claim 12, wherein the first sub-pixels and the second sub-pixels are electrically connected to a same signal line, and are configured to emit light concurrently or substantially simultaneously.

20. A display apparatus comprising:
a first display area in which sub-pixels are arranged; and
a second display area adjacent to the first display area, and comprising:
a third pixel area in which there is a fourth pixel having a rectangular shape in a plan view and comprising two first sub-pixels, one second sub-pixel, and two third sub-pixels; and
transmission areas surrounding the third pixel area, and
wherein the first sub-pixels are spaced apart from each other in a first direction at a lower portion of the third pixel area,
wherein the second sub-pixel is at a center of the third pixel area, and
wherein the third sub-pixels are spaced apart from each other in the first direction at an upper portion of the third pixel area.

21. The display apparatus of claim 20, wherein a shortest distance between one of the first sub-pixels and an adjacent first transmission area of the transmission areas, and a shortest distance between the one of the first sub-pixels and an adjacent second transmission area of the transmission areas, are substantially equal.

22. The display apparatus of claim 20, wherein a shortest distance between one of the third sub-pixels and an adjacent first transmission area of the transmission areas, and a shortest distance between the one of the third sub-pixels and an adjacent third transmission area of the transmission areas, are substantially equal to each other.
